(19) United States
(12) Patent Application Publication
(10) Pub. No.: US 2002/0051944 A1
(43) Pub. Date: May 2, 2002

(54) Pattern forming method of forming a metallic pattern on a surface of a circuit board by electroless plating

(75) Inventors: Hisaya Takahashi, Toyama (JP); Masanobu Izaki, Nara (JP)

Correspondence Address: YOUNG & THOMPSON, 745 SOUTH 23RD STREET 2ND FLOOR, ARLINGTON, VA, 22202

(73) Assignee: Nec Corporation and Masanobu Izaki

(21) Appl. No.: 09/984,176

(22) Filed: Oct. 29, 2001

(30) Foreign Application Priority Data
Oct. 27, 2000 (JP) 2000-328983

(51) Int. Cl. G03F 7/00

(52) U.S. Cl. 430/324; 430/322; 427/98

(57) ABSTRACT

A circuit board having a surface thereof on which a catalytic layer is formed initially and a photosensitive plating resist is subsequently applied in a manner such that the applied plating resist is subjected to an exposure for patterning a desired shape of pattern to be then developed, and that by the use of the patterned plating resist, a metallic pattern is formed by the electroless plating. The light of a specific wavelength, which hardens the plating resist, is absorbed by the catalytic layer and does not cause any halation at a boundary between the catalytic layer and the plating resist. Thus, since the plating resist can be patterned in a correct shape, the metallic pattern can be formed to have an accurate shape.

### BACKGROUND OF THE INVENTION

1. Field of the Invention

The present invention generally relates to a method of forming a metallic pattern on a surface of a circuit board, and more particularly to a method of forming the metallic pattern by electroless plating.

2. Description of the Related Art

At present, a metallic pattern member consisting of a circuit board having a surface thereof on which a wiring pattern and other metallic patterns such as a connecting pad are formed, is used for an integrating circuit device and a printed circuit board. As a method of forming the metallic pattern on the circuit board, there are various kinds of processes. For example, there are a subtractive process and an additive process, in which processes a metallic pattern is formed by metallic plating.

These processes can be further classified into various kinds, and in one conventional subtractive process, a metallic layer is formed on a surface of a circuit board by electroless plating to coat the layer's surface with a photosensitive plating resist, and further a beam of light having a specific wavelength is radiated onto the surface of the plating resist so that a desired pattern is exposed and is then developed. Namely, the plating resist is patterned by this development to be used as a mask for patterning the metallic layer so as to eventually create a metallic pattern. Though the formed metallic pattern on the surface of the circuit board may be directly used as it is, the metallic pattern is generally used as a ground for increasing the thickness of the pattern by electrolytic plating.

On the other hand, in a general additive process, a photosensitive plating resist is initially applied onto the surface of a circuit board, and subsequently, the plating resist is exposed to the radiation of a beam of light having a specific wavelength to develop a desired pattern thereon. Then, a metallic pattern is formed by a metallic plating onto a surface portion of the circuit board, which is uncoated by the plating resist patterned by the above-mentioned development.

As typical additive processes, there are a full additive process and a semi-additive process, respectively. In a general full additive process, a metallic pattern is directly formed by the electroless plating method onto a surface portion of a circuit board, which is uncoated by a patterned plating resist, and the plating resist is left as it is to be used as an insulating layer.

While, in a general semi-additive process, a metallic layer is formed on the surface of a circuit board by electroless plating, and then a plating resist is applied to the metallic layer, so as to subsequently pattern the plating resist. Then, a metallic pattern is formed onto a surface portion of the metallic layer, which is uncoated by the patterned plating resist. Since the entire portion of the metallic layer except for the portion located below the formed metallic pattern is thereafter removed together with all of the plating resist, the metallic pattern may thereby be prevented from being short-circuited by any portion of the metallic layer located below the metallic layer.

With the described subtractive process, the full additive process, and the semi-additive process, the metallic layer is formed on the surface of the circuit board. However, when the circuit board is made of a dielectric material such as a glass and a ceramic material, it is difficult to deposit a metallic pattern directly onto the surface of the circuit board. Therefore, all of the above-mentioned processes actually employ such a process in that the surface of the circuit board is subjected to a roughening and catalyzing treatment before a plating resist is applied onto the surface of the circuit board for the purpose of permitting a metallic layer to be easily deposited onto the board surface by the electroless plating. This catalyzing treatment for the electroless plating is usually conducted by the use of a material called sensitizer & activator catalysis that is made of a wide-band gap oxide such as tin oxide.

That is to say, in the full additive process according to the conventional art, a layer of tin oxide is formed by coating on the surface of a circuit board made of glass or ceramic material, and a plating resist is applied thereon so that the plating resist is exposed to a light and developed to pattern the plating resist. Then, surface portions of the circuit board that is uncoated by the patterned plating resist is subjected to the electroless plating to create a metallic pattern. Further, in the semi-additive process and the subtractive process according to the conventional art, a layer of tin oxide is applied by coating onto the surface of a circuit board, and then a metallic layer is formed by the electroless plating.

As described above, when a metallic pattern is formed by any one of the subtractive, full additive, and semi-additive processes, if a filmy tin oxide layer is formed beforehand onto the surface of a circuit board, it is possible to successfully create a metallic layer by the electroless plating.

Nevertheless, when the present inventors actually created, by an experiment, a metallic pattern on the surface of a circuit board by adopting the full additive process after a tin oxide layer is filmed onto the surface, it was confirmed that the shape of cross-section of the metallic pattern could not be rectangular, and also minute lines of the metallic pattern were formed to have an unequal width.

### SUMMARY OF THE INVENTION

An object of the present invention is to provide a pattern forming method capable of forming a metallic pattern, while permitting the formed pattern to have a cross-section thereof in a correct rectangular shape and also to have an accurately equal width when formed into lines.

In the pattern forming method according to the present invention, a predetermined catalytic layer is formed on a surface of a circuit board, and a photosensitive plating resist is applied onto the formed catalytic layer so that the plating resist is patterned into a desired shape of a pattern by an exposure to a light. The patterned plating resist is then developed and is used for forming a metallic pattern in a manner such that at least a part of the metallic pattern is formed by the electroless plating.

In the pattern forming method according to the present invention, as described above, prior to forming a metallic pattern by the electroless plating, the catalytic layer is formed on the surface of the circuit board, and therefore the forming of the metallic pattern by the electroless plating can be very successfully conducted. Further, although the plating resist is hardened by reacting against a beam of light having a specific wavelength, since the light having the specific wavelength can be absorbed by the above-mentioned catalytic layer, for example, even when the plating resist is subjected to exposure to the light after it is applied onto the surface of the catalytic layer, the light to which the plating resist is exposed does not cause any halation at a boundary between the plating resist and the catalytic layer. Thus, the plating resist can be accurately patterned to have a desired shape. Accordingly, by the use of this patterned plating resist, a metallic pattern can be formed to have a cross-section thereof in a correct rectangular shape and also to have an accurate line width.

In accordance with another pattern forming method according to the present invention, a catalytic layer made of wide-band gap chemical compound is formed on a surface of a circuit board, and a 1B element is fed to the formed catalytic layer. Then, a part of the 1B element fed to the catalytic layer is substituted with a 8-3 element, and onto the surface of the catalytic layer in which a part of the 1B element is substituted with the 8-3 element, a photosensitive plating resist, which is hardened when it reacts against a light having a specific wavelength when it is applied. The plating resist is then exposed to the radiation of the beam of light having the above-mentioned specific wavelength to be patterned and developed into a desired shape. Thereafter, the patterned plating resist is used for forming a metallic pattern on the surface of the catalytic layer in a manner such that at least a part of the metallic pattern is formed by the electroless plating.

In the secondly described pattern forming method according to the present invention, the above-mentioned catalytic layer absorbs the light having the specific wavelength and hardening the plating resist. Thus, the light to which the plating resist is exposed for patterning does not cause any halation at the boundary between the catalytic layer and the plating resist. Therefore, the plating resist can be accurately patterned in a desired shape, and accordingly a metallic pattern formed by the use of the patterned plating resist can be formed to have an accurate rectangular cross-sectional shape as well as a correct line width.

Particularly, since the catalytic layer is made of wide-band gap chemical compound to which the 1B element is fed, and since a part of the fed 1B element of the catalytic layer is substituted by 8-3 element, it is possible to promote the deposition of metal due to the electroless plating and to realize a catalytic layer able to successfully absorb a light of the specific wavelength, which is effective for hardening the plating resist.

The above-described pattern forming method of the present invention may be equally applicable to the full additive process, the semi-additive process and the subtractive process.

For example, when it is applied to the full additive process, a metallic pattern is formed by the electroless plating on a bare surface of a catalytic layer, which is uncoated by any patterned plating resist. In this full additive process, the plating resist is exposed to the light after it is applied to the surface of the catalytic layer. However, the light for the exposure of the plating resist does not cause any halation at a boundary phase between the plating resist and the catalytic layer.

Also, when the pattern forming method of the present invention is applied to the semi-additive process, a metallic layer is formed on a surface of a catalytic layer by the electroless plating prior to application of a plating resist. Then, a metallic pattern is formed by the electroless plating on the bare surface of the metallic layer that is uncoated by the patterned plating resist.

Further, when the pattern forming method of the present invention is applied to the subtractive process, a metallic layer is formed on a surface of a catalytic layer by the electroless plating prior to application of a plating resist. Then, a portion of the metallic layer, which is not covered by the patterned plating resist, is removed, so that the remaining portion of the metallic layer is used as a ground for permitting a metallic pattern to be formed thereon by the electroless plating.

In another embodiment of the present invention, the catalytic layer may be formed by at least one of wide-band gap chemical compounds of tin, zinc, indium, and titanium. Also, the wide-band gap chemical compound is composed of at least one of an oxide and a sulfide. Further, the wide-band gap chemical compound may be composed of a tin oxide, and the 1B element consists of silver, and the 8-3 element consists of palladium. Furthermore, the light for hardening the plating resist contains therein at least ultraviolet rays. Also, at least a part of the light for hardening the plating resists has a wavelength located in the waveband of 370 through 460 (nm).

It should be noted that, the wide-band gap chemical compound referred to in the present invention means a wide chemical compound of a band gap ranging from 3 through 4 (eV), and accordingly, for example, it may be an oxide and a sulfide of tin, zinc, indium, and titanium.

Further, the 1B element means one of the elements in the family 1B of the periodic table, thus it may be copper, silver, or gold.

Furthermore, the 8-3 element means one of elements belonging to the third line of the family VIII of the periodic table, and accordingly it can be, for example, nickel, palladium or platinum.

The above and other objects, features and advantages of the present invention will become more apparent from the following description with reference to the accompanying drawings, which illustrate examples of the present invention.

### BRIEF DESCRIPTION OF THE DRAWINGS

FIG. 1 is a flow diagram illustrating a front half of the pattern forming method according to an embodiment of the present invention;

FIG. 2 is a flow diagram illustrating a rear half of the same pattern forming method;

FIG. 3 is a block diagram illustrating a pattern forming method; and,

FIG. 4 is a graphical characteristic view illustrating the transmittance of various tin oxides.

### DETAILED DESCRIPTION OF THE PREFERRED EMBODIMENTS

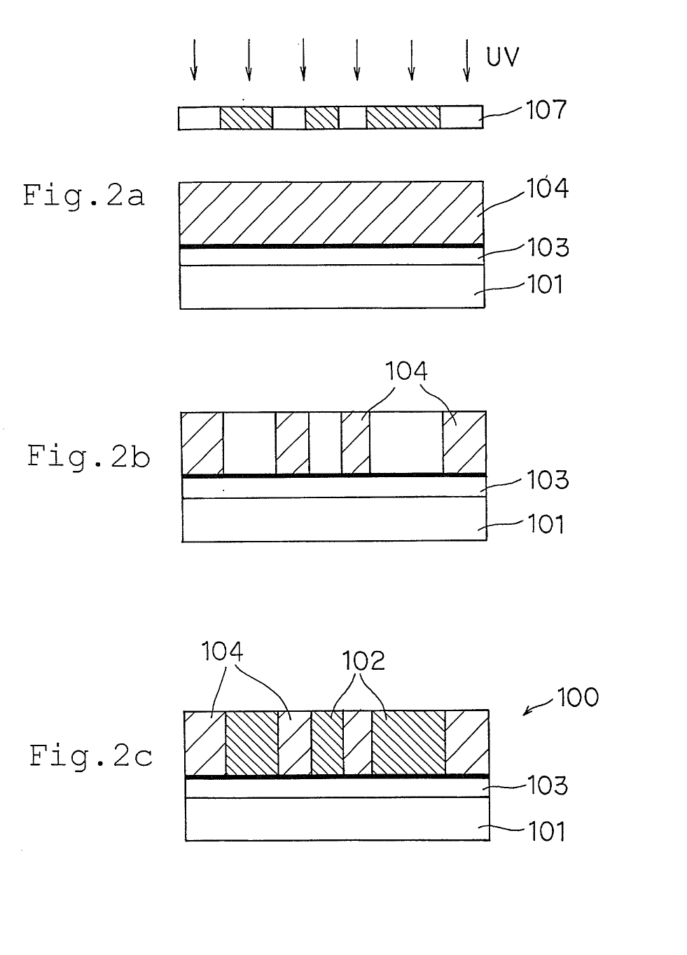

The description of an embodiment of the present invention will be provided herein below with reference to the drawings. First of all, a printed circuit board 100, which is a metallic pattern member according to the present embodiment, includes a circuit board 101 as shown in FIG. 2c. Circuit board 101 has a surface thereof on which printed circuits are formed by metallic patterns 102.

More specifically, circuit board 101 consists of an insulating material such as glass or ceramic material, and has a surface thereof on which a catalytic layer 103 made of tin oxide that is one of the wide-band gap chemical compounds is formed. Catalytic layer 103 has a surface thereof on which a filmy layer of a plating resist 104 is deposited. Plating resist 104 is formed with grooves extending to the surface of catalytic layer 103 and having predetermined patterns, and these grooves are filled with metallic patterns 102 of copper.

At this stage, the description of the pattern forming method according to the present embodiment, which is used for manufacturing the above-described printed circuit board 100, will be sequentially provided below.

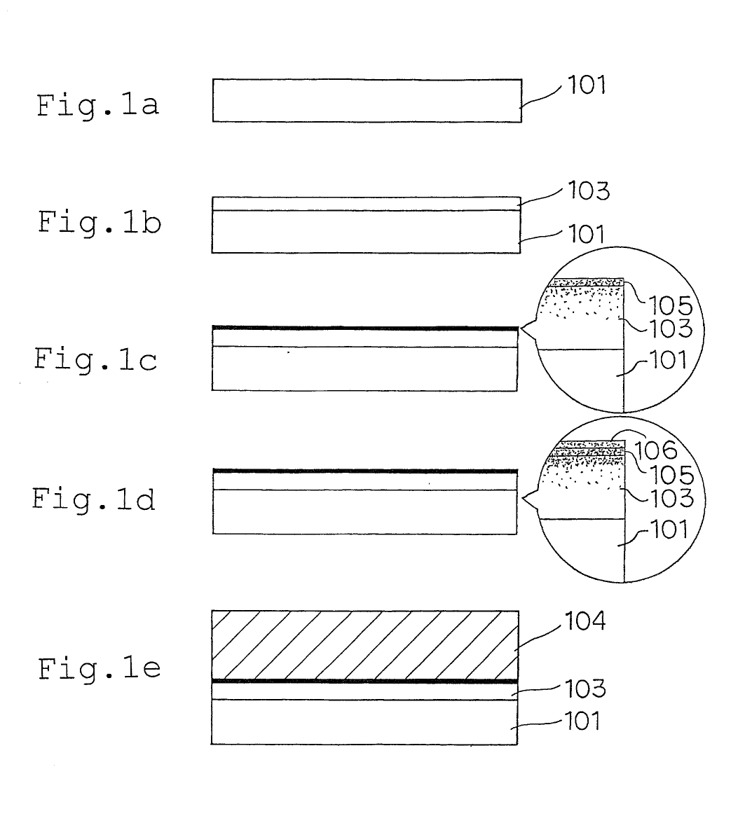

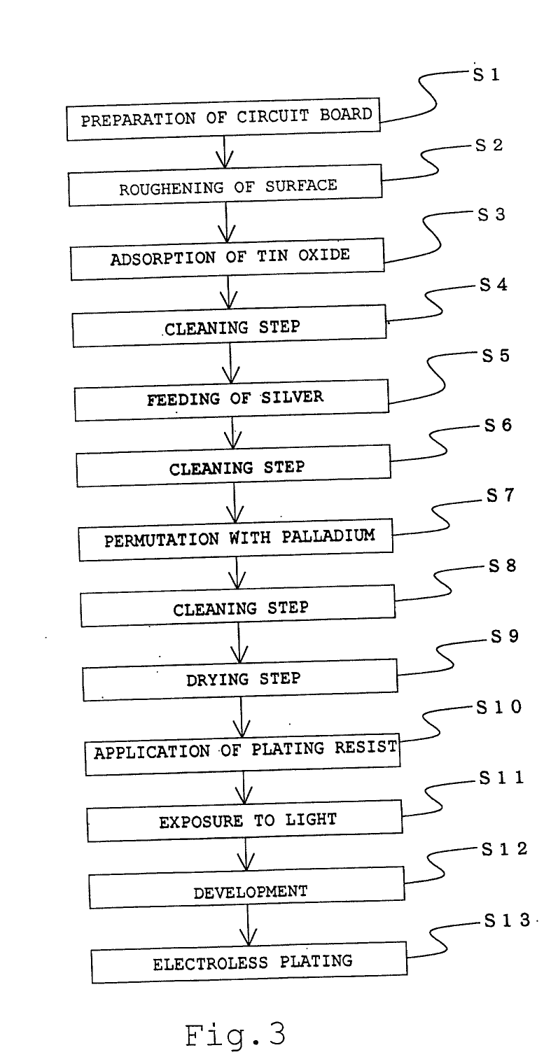

As shown in Figs. 1a and 3, a circuit board 101 is prepared in Step S1, and in Step S2, the surface of the board is roughened to an Rms roughness of approximately 1.00 through 10.00 (nm) Subsequently, circuit board 101 having the roughened surface is dipped in a liquid bath containing tin oxide therein so that the tin oxide is adsorbed, in Step S3, by the dipping process on the roughened surface of circuit board 101 to thereby homogeneously create catalytic layer 103 of approximately 1.0 through 80 (nm) thickness.

Subsequently, in Step S4, circuit board 101 with catalytic layer 103 formed on its surface is cleaned, and thereafter in step S5, board 101 is dipped in a liquid bath of silver that is one of the 1B elements, so that the silver is fed to catalytic layer 103. In this instant, as shown in Fig. 1c, the silver is actually deposited onto the surface of catalytic layer 103 so as to form an extremely thin film 105 of silver, and thus the silver is molecularly connected to the tin oxide in an uppermost layer of catalytic layer 103.

In Step S6, circuit board 101 with catalytic layer 103 to which the silver is given is cleaned, and is then dipped in a liquid bath of palladium that is one of the 8-3 elements, so that, in Step S7, the palladium is partially substituted with the silver of catalytic layer 103.

In this instant, as shown in FIG. 1d, the palladium is actually deposited onto the surface of catalytic layer 103 to form an extremely thin film 106 of palladium, and therefore a part of the silver connected to the tin oxide in the upper layer of catalytic layer 103 is molecularly substituted with the palladium.

In Steps S8 and S9, circuit board 101 is cleaned and dried, and thereafter, in Step S10, a photosensitive plating resist 104 is applied as shown in Fig. 1e, to the surface of catalytic layer 103 in a manner similar to the conventional process.

As shown in FIG. 2a, in Step S11, plating resist 104 is masked by a patterning mask 107 of a desired pattern, and is exposed to the ultraviolet rays of 370 through 460 (nm) wavelengths. Subsequently, as shown in FIG. 2b, in Step S12, the light-exposed plating resist 104 is subjected to the developing treatment to obtain the patterned plating resist 104 having the pattern similar to that of patterning mask 107. Thus, in Step S13, onto a bare surface portion of catalytic layer 103, which is uncoated with the patterned plating resist 104, a metallic pattern 102 of copper is formed by the electroless plating, so that printed circuit board 100 shown in FIG. 2c is completed.

In the described pattern forming method of the present embodiment, since catalytic layer 103 is formed on the surface of circuit board 101 prior to the creation of metallic pattern 102 by the electroless plating similar to that of the conventional method, metallic pattern 102 can be successfully formed by the electroless plating.

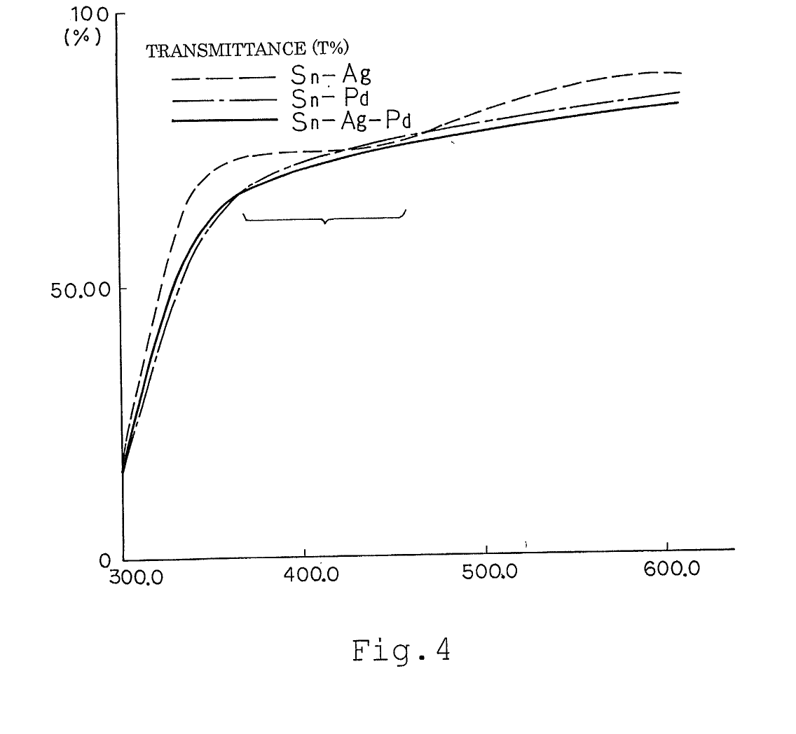

However, differing from the conventional method, catalytic layer 103 consisting of the tin oxide is fed with the silver, prior to the exposure of plating resist 104, and a part of the fed silver is substituted with palladium. Thus, as best shown in FIG. 4, catalytic layer 103 subjected to the above-mentioned treatment is brought into such a condition that layer 103 is able to successfully absorb the light of 370 through 460 (nm) wavelengths, compared with the tin oxide to which only either the silver or the tin oxide is fed.

Moreover, as the ultraviolet rays used for the exposure of plating resist 104 have wavelengths belonging to the above-mentioned waveband, such ultraviolet rays for the exposure of plating resist 104 can be successfully absorbed by the uppermost layer of catalytic layer 103, and therefore the ultraviolet rays for the exposure of plating resist 104 do not cause any halation at a boundary phase between plating resist 104 and catalytic layer 103.

Therefore, in the pattern forming method according to the present embodiment, plating resist 104 can be accurately patterned in a desired shape, and accordingly by the use of the patterned plating resist 104, metallic pattern 102 can be formed to have a correct rectangular cross-sectional shape as well as accurate line widths.

In the described embodiment, an example of manufacturing a printed circuit board as a metallic pattern member is described. Nevertheless, for example, by the adoption of the pattern forming method according to the present embodiment, it is possible to create metallic patterns of an integrated circuit device.

Further, in the above-described embodiment, the pattern forming method is disclosed with an example of the full additive process in which a plating resist 104 is applied to the surface of catalytic layer 103. Nevertheless, it is to be noted that the pattern forming method of the present invention may be equally adapted for either one of the semi-additive process and the subtractive process.

In the semi-additive process, a metallic layer is formed by the electroless plating on the surface of a catalytic layer 103 prior to application of a plating resist 104, and a metallic pattern 102 is formed onto a surface portion of the metallic layer, which is bare of the patterned plating resist 104.

Also, in the subtractive process, a metallic layer is formed by the electroless plating on the surface of a catalytic layer 103 prior to application of a plating resist 104, and then a portion of the metallic layer, which is bare of the patterned plating resist 104, is removed. Thereafter, the remaining metallic layer is used as a ground on which a metallic pattern 102 is formed by the electroless plating.

In the above-described semi-additive and subtractive processes, a metallic layer is evenly formed by the electroless plating on the surface of catalytic layer 103 before plating resist 104 is applied. Therefore, the light used for the exposure of plating resist 104 cannot be prevented from causing halation by catalytic layer 103. Nevertheless, as heretofore described, catalytic layer 103, which consists of the tin oxide to which the silver is fed in such a manner that a part of the given silver is thereafter substituted with the palladium, has a large electric resistance ranging from approximately 10E8 through 10E13 (Ω/cm²) while exhibiting a high insulation. Therefore, even if circuit board 101 is electrically conductive, metallic pattern 102 can be formed without provision of any specific insulating layer.

Further, in the described embodiment, catalytic layer 103 consists of the tin oxide as one example. However, alternatively, catalytic layer 103 may consist of a wide-band gap chemical compound of zinc, indium, and titanium, and this wide-band gap chemical compound per se may be a sulfide in addition to an oxide.

Furthermore, in the example of the described embodiment, the formation of catalytic layer 103, the feeding of the silver, and the substitution of the silver with the palladium are all implemented by the dipping process. However, a part of them or all of them may be alternatively implemented by a sputtering process or a spray-pyrolysis process. Furthermore, in the above-described embodiment, catalytic layer 103 is fed with the silver, as an example. However, anyone of the 1B elements may be alternatively fed to the catalytic layer. In addition, a part of the silver may be substituted with any one of the 8-3 elements in addition to the described palladium.

While preferred embodiments of the present invention have been described using specific terms, such description is for illustrative purpose only, and it is to be understood that changes and variations may be made without departing from the spirit or scope of the following claims.

What is claimed is:

1. A pattern forming method comprising the steps of:
forming a catalytic layer, which permits a metal to be readily deposited, on a surface of a circuit board;
applying a photosensitive plating resist, which is hardened by reacting with a light having a specific wavelength, onto the surface of said circuit board;
exposing said plating resist to a radiation of said light having said specific wavelength to thereby form a desired shape of a pattern;
developing said plating resist which is exposed by said pattern; and
forming a metallic pattern on said surface of said circuit board in a manner such that at least a part thereof is formed by an electroless plating, by the use of said plating resist patterned by said developing; and
said catalytic layer being composed of a predetermined chemical compound able to absorb said light having said specific wavelength.

2. A pattern forming method of forming a metallic pattern on a surface of a circuit board comprising the steps of:
forming a catalytic layer, which permits a metal to be readily deposited, on the surface of said circuit board by employing a wide-band gap chemical compound;
giving the formed catalytic layer with a 1B element;
substituting a part of the given 1B element with a 8-3 element;
applying a photosensitive plating resist, which is hardened by reacting with a light having a specific wavelength, onto the surface of said catalytic layer in which said 1B element is partly substituted with said 8-3 element;
exposing said plating resist to a radiation of the light having said wavelength to thereby form a desired shape of a pattern;
developing said plating resist which is exposed by said pattern; and
forming said metallic pattern on the surface of said catalytic layer in a manner such that at least a part thereof is formed by an electroless plating, by the use of said plating resist patterned by the developing.

3. The pattern forming method according to claim 1, further comprising the step of, as a full additive process:
forming said metallic pattern by the electroless plating on the surface of said catalytic layer, which is bare of said patterned plating resist.

4. The pattern forming method according to claim 2, further comprising the step of, as a full additive process:
forming said metallic pattern by the electroless plating on the surface of said catalytic layer, which is bare of said patterned plating resist.

5. The pattern forming method according to claim 1, further comprising the steps of, as a semi-additive process:
forming a metallic layer by the electroless plating on the surface of said catalytic layer prior to applying said plating resist; and
forming said metallic pattern by the electroless plating on the surface of said metallic layer, which is bare of said patterned plating resist.

6. The pattern forming method according to claim 2, further comprising the steps of, as a semi-additive process:
forming a metallic layer by the electroless plating on the surface of said catalytic layer prior to applying said plating resist; and
forming said metallic pattern by the electroless plating on the surface of said metallic layer, which is bare of said patterned plating resist.

7. The pattern forming method according to claim 1, further comprising the steps of, as a subtractive process:
forming a metallic layer by the electroless plating on the surface of said catalytic layer prior to applying said plating resist;
removing said metallic layer, which is bare of said patterned plating resist; and
forming said metallic pattern by the electroless plating on a ground, which is formed by said metallic layer that still remains after said removing.

8. The pattern forming method according to claim 2, further comprising the steps of, as a subtractive process:
forming a metallic layer by the electroless plating on the surface of said catalytic layer prior to applying said plating resist;
removing said metallic layer, which is bare of said patterned plating resist; and
forming said metallic pattern by the electroless plating on a ground, which is formed by said metallic layer that still remains after said removing.

9. The pattern forming method according to claim 1, wherein said catalytic layer is composed of at least one of wide-band gap chemical compounds of tin, zinc, indium, and titanium.

10. The pattern forming method according to claim 2, wherein said catalytic layer is composed of at least one of wide-band gap chemical compounds of tin, zinc, indium, and titanium.

11. The pattern forming method according to claim 9, wherein said wide-band gap chemical compound is composed of at least one of an oxide and a sulfide.

12. The pattern forming method according to claim 10, wherein said wide-band gap chemical compound is composed of at least one of an oxide and a sulfide.

13. The pattern forming method according to claim 9, wherein said wide-band gap chemical compound is composed of a tin oxide, said 1B element is composed of silver, and said 8-3 element is composed of palladium.

14. The pattern forming method according to claim 10, wherein said wide-band gap chemical compound is composed of a tin oxide, said 1B element is composed of silver, and said 8-3 element is composed of palladium.

15. The pattern forming method according to claim 1, wherein the light for hardening said plating resist contains therein at least ultraviolet rays.

16. The pattern forming method according to claim 2, wherein the light for hardening said plating resist contains therein at least ultraviolet rays.

17. The pattern forming method according to claim 1, wherein the light for hardening said plating resist has wavelengths, at least a part of which are located in the band ranging from 370 through 460 (nm).

18. The pattern forming method according to claim 2, wherein the light for hardening said plating-resist has wavelengths, at least a part of which are located in the band ranging from 370 through 460 (nm).

19. A metallic pattern member manufactured by the pattern forming method according to claim 2, wherein said metallic pattern is formed on the surface of said circuit board via said catalytic layer, and said 1B element is fed to said catalytic layer, a part of said given 1B element being substituted with said 8-3 element.
